(19) United States
(12) Patent Application Publication
(10) Pub. No.: US 2025/0246557 A1
(43) Pub. Date: Jul. 31, 2025

(54) CONTROL OF SUBSTRATE DEFORMATION DURING MANUFACTURING PROCESSES

(71) Applicant: Applied Materials, Inc., Santa Clara, CA (US)

(72) Inventors: Pradeep Kumar Subrahmanyan, San Jose, CA (US); Wonjae Lee, Fremont, CA (US)

(21) Appl. No.: 19/034,428

(22) Filed: Jan. 22, 2025

Related U.S. Application Data
(60) Provisional application No. 63/625,855, filed on Jan. 26, 2024.

(51) Int. Cl. H01L 23/00; H01L 21/3105; H01L 21/66

(52) U.S. Cl. CPC H01L 23/562; H01L 21/3105; H01L 22/12

(57) ABSTRACT

Disclosed techniques include obtaining a wafer with a front side supporting deposited features and identifying first characteristics of one or more protective films and second characteristics of one or more stress-compensation layers (SCLs). The techniques further include forming the protective film(s) on the front side of the wafer and depositing the SCLs on the back side of the wafer. The techniques further include subjecting at least one SCL to a stress-modulation beam causing a saddle deformation of the wafer to be reduced and removing the protective film(s) from the one or more deposited features.

### RELATED APPLICATIONS

This application claims the benefit of the U.S. Provisional Patent Application No. 63/625,855, filed Jan. 26, 2024, entitled “CONTROL OF SUBSTRATE DEFORMATION DURING MANUFACTURING PROCESSES,” the contents of which are being incorporated in their entirety by reference herein.

### TECHNICAL FIELD

The disclosure pertains to semiconductor manufacturing, including processing of wafers and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### SUMMARY

Disclosed herein, according to one embodiment, is a method of manufacturing a semiconductor device, the method including identifying first characteristics of one or more protective films, the first characteristics including an amount of stress in each of the one or more protective films, and identifying second characteristics of one or more stress-compensation layers (SCLs), the second characteristics including an amount of stress of each of the one or more SCLs. The method further includes forming, on a front side of a substrate, the one or more protective films having the first characteristics and forming, on a back side of the substrate, the one or more SCLs having the second characteristics. The method further includes subjecting at least one SCL of the one or more SCLs to a stress-modulation beam, the SCL causing a saddle deformation of the substrate to be reduced, and removing the one or more protective films.

In another embodiment, disclosed is a system that includes a memory and a processing device communicatively coupled to the memory. The processing device is to cause performance of operations that include identifying first characteristics of one or more protective films, the first characteristics including an amount of stress in each of the one or more protective films, and identifying second characteristics of one or more SCLs, the second characteristics including an amount of stress of each of the one or more SCLs. The operations further include forming, on a front side of a substrate, the one or more protective films having the first characteristics and forming, on a back side of the substrate, the one or more SCLs having the second characteristics. The operations further include subjecting at least one SCL of the one or more SCLs to a stress-modulation beam, the SCL causing a saddle deformation of the substrate to be reduced, and removing the one or more protective films.

In another embodiment, disclosed is a semiconductor manufacturing system having one or more processing chambers, the semiconductor manufacturing system to identify first characteristics of one or more protective films, the first characteristics including an amount of stress in each of the one or more protective films, and identify second characteristics of one or more SCLs, the second characteristics including an amount of stress of each of the one or more SCLs. The semiconductor manufacturing system is further to form, on a front side of a substrate, the one or more protective films having the first characteristics and form, on a back side of the substrate, the one or more SCLs having the second characteristics. The semiconductor manufacturing system is further to subject at least one SCL of the one or more SCLs to a stress-modulation beam, the SCL causing a saddle deformation of the substrate to be reduced, and remove the one or more protective films.

### BRIEF DESCRIPTION OF THE DRAWINGS

The present disclosure will be understood more fully from the detailed description given below and from the accompanying drawings of various embodiments of the disclosure.

FIGS. 1A-1F illustrate schematically a process of mitigating low-to-moderate saddle deformations in wafer processing using both front side protective films and back side stress-compensation layers (SCLs), according to at least one embodiment.

FIGS. 2A-2G illustrate schematically a process of mitigating moderate-to-high saddle deformations in wafer processing using iterative front side protective film and back side SCL deposition, according to at least one embodiment.

FIGS. 3A-3B illustrate schematic distribution of vacancies created by ions of different masses irradiating a stress-compensation layer having multiple portions, according to at least one embodiment.

FIGS. 4A-4C illustrate an example processing of a wafer using a stress-modulation beam as part of mitigation of moderate-to-high saddle deformations in wafer processing, according to at least one embodiment.

FIGS. 5A-5F illustrate schematically a process of mitigating a wafer deformation using back side stress-compensation layers with alternating stress, according to at least one embodiment.

FIGS. 6A-6B illustrate example position-dependent doses of particles delivered by a stress-modulation beam to stress-compensation layers deposited on wafers to mitigate a saddle deformation of the wafer, according to at least one embodiment.

FIGS. 7A-7E illustrate schematically another example process of mitigating a wafer deformation using back side stress-compensation films of alternating stress, according to at least one embodiment.

FIG. 8 illustrates an example Zernike polynomial decomposition of one actual deformation (top left) of a wafer, in arbitrary units, into a paraboloid bow deformation (top right), a saddle deformation (bottom left), and a residual deformation, (bottom right), according to at least one embodiment.

FIG. 9 is a flowchart illustrating an example method of mitigation of wafer deformation using front side protection films and back side stress-compensation layers, in accordance with at least one embodiment.

FIGS. 10A-10B illustrates schematically an irradiation system capable of performing irradiation of stress compensation layers, according to at least one embodiment.

FIG. 11 depicts a block diagram of an example computer system capable of supporting operations of the present disclosure, according to at least one embodiment.

### BRIEF DESCRIPTION OF THE TABLES

Table 1 illustrates an example stress mitigation with back side stress-compensation film deposition.

Table 2 illustrates an example stress mitigation with a front side protective film and a back side stress-compensation layer.

Table 3 illustrates an example stress mitigation with a front side protective film and a back side stress-compensation layer for a high saddle deformation.

Table 4 illustrates an example stress mitigation with multiple front side protection films and back side stress-compensation layers for a high saddle deformation.

Table 5 illustrates an example stress mitigation with multiple stress-compensation layers of alternating stress.

The present disclosure will be understood more fully from the detailed description given below and from the accompanying drawings of various embodiments of the disclosure.

### DETAILED DESCRIPTION

Modern technology often aims to maximize chip area utilization by manufacturing three-dimensional devices with vertical stacks of multiple layers of semiconducting structures. For example, in NAND flash memory devices, lateral relative arrangement (CMOS near Array, or CnA) of memory cells (e.g., floating gate transistors) and peripheral transistors (e.g., CMOS circuitry used to support write/read operations with memory cells) has mostly given way to a vertical arrangement (CMOS under Array, or CuA) in which peripheral CMOS circuitry is disposed below an array of memory cells. In some instances, stacks of layers of memory cells can be manufactured on top of other stacks creating a structure in which precise alignment of various features within the layers is important for proper functioning of the manufactured devices. In one example, a stack of multiple (e.g., a hundred or more) alternating oxide (O) and nitride (N) layers (e.g., silicon oxide and silicon nitride layers, in one example), polycrystalline silicon layers, and/or other features can be deposited on one side (referred to as the front side herein) of a substrate, e.g. a silicon wafer, and then covered with a mask layer (e.g., a carbon hard mask). A photoresist layer can be deposited on the mask layer with a defined pattern of holes (channel holes), slits, and/or various other openings that are to be transferred to the stack of ON layers via the mask. A photolithography can be performed to open the mask according to the defined pattern (with the photoresist material protecting unexposed areas of the mask) and allow access to the stack of ON layers. An etching process can be carried out to etch the regions of the ON layers located under the opened portions of the mask to form deep vertical channels and/or slits that can extend all the way through the stack and down to the wafer. The channels/slits can then be used to deliver target materials across various ON layers, e.g., to replace silicon nitride in ON layers with conducting materials (such as Tungsten) and to form multi-layered transistor arrays within the vertical channels, and/or the like. Various other layers/films can be deposited on wafers, e.g., polycrystalline silicon layers, carbon and polymer protective films, and/or the like. In another example of a three-dimensional (3D) Dynamic Random-Access Memory (DRAM) manufacturing, a stack of alternating silicon-germanium alloy (Si₁₋ₓGeₓ) layers and silicon (e.g., epitaxial silicon) layers can be deposited on top of a silicon substrate.

In many instances, substrates, such as wafers, with such complex features deposited thereon may need to be handled by various end effectors engaging the front side of the wafer (where the features are deposited). For example, a manufacturing process can include flipping the wafer, performing various operations on the wafer's back side (e.g., thinning, deposition of additional features, etc.), and/or the like. To protect deposited features from the end effectors, the features can be temporarily covered with a protective film (e.g., a silicon nitride film, an amorphous carbon layer, and/or the like) that is subsequently removed, e.g., to allow additional features to be formed or deposited on top of the previously formed features.

The arrays of transistors and/or other features deposited into the stack of layers may have to be precisely aligned with the previously formed structures (e.g., source lines of conducting circuits that support electronic operations of the transistor arrays). Deposition of various films, circuitry, and other features on wafers, however, leads to stresses and deformations of the wafers. Such stresses result from direct mechanical (elastic) interaction between wafers and features, a mismatch of thermal expansion coefficients of wafer/film/conductor materials, wafer thinning, cutting of the deposited features, and/or other processing operations that can be performed on the wafer structures (e.g., protective film/mask deposition, etc.). Deformation can lead to misalignment of manufactured features and result in substandard or inoperable devices, including wafers/dies with cracks, delaminations, inconsistent electrical contacts, mismatched circuitry, and/or the like. Correcting wafer deformations is, therefore, important for achieving die/device quality.

Existing technology includes several methods that mitigate wafer deformation. For example, a deformed (warped) wafer with various films and features deposited on the front side can be coated on the back side with a film, referred to as stress-compensation layer (SCL) herein, that exerts compression stress or tensile stress on the wafer. An SCL can impart a uniform (or global) stress to the entire wafer and reduce an amount of deformation of the wafer. Additional stress-modification can be achieved by irradiating the SCL with a stress-modulation beam that modify stress in the SCL to correct the deformation of the underlying wafer. The stress-modulation beam can include matter particles (e.g., ions, electrons), electromagnetic waves (e.g., UV light, visible light, infrared light, etc.), and/or a suitable combination thereof. Irradiation by a stress-modulation beam can be performed globally or locally (e.g., to certain selected areas of the wafer), e.g., to mitigate saddle-shaped deformations of wafers. To reduce the remaining deformation, the stress-modulation beam can deliver a non-uniform (X- and Y-dependent) dose of radiation (e.g., of ions or other particles) to suitably chosen areas of the SCL (e.g., edge regions) to flatter the wafer.

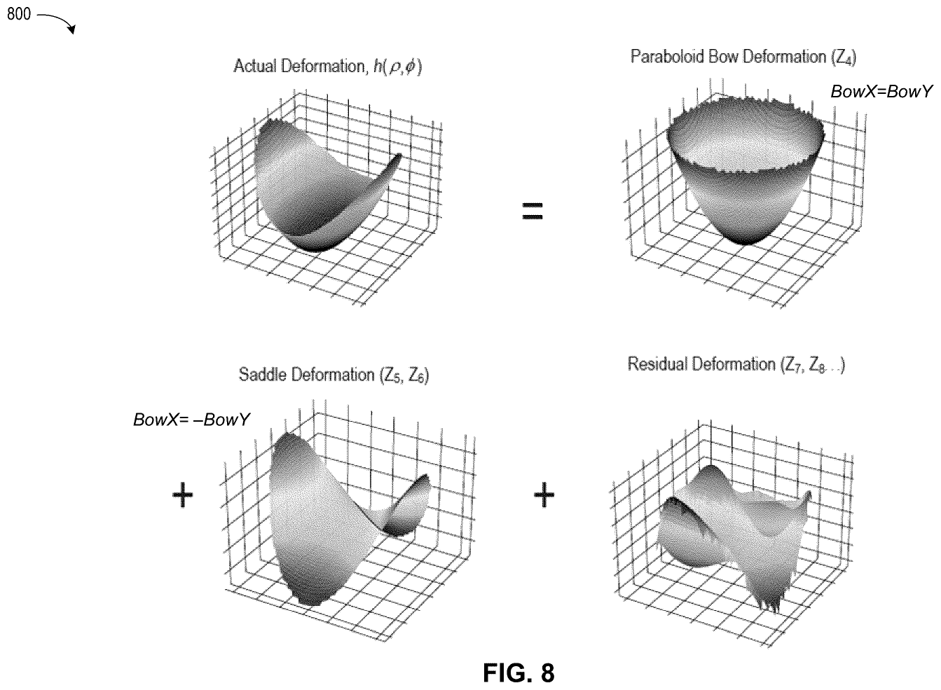

More specifically, a profile of wafer deformation h(X, Y) can often be characterized approximately by an amount of bow along two specially chosen axes X and Y of the wafer (considered to be the principal axes of the deformation) with parameters BowX and BowY describing the degree of deformation along the respective axes, e.g., BowX=h(R, 0)−h(0,0) and BowY=h(0, R)−h(0,0), where R is the radius of the wafer (e.g., R=15 cm, in one example). An isotropic (paraboloid) deformation (cf. FIG. 8 for illustration) is characterized by BowX=BowY, while a wafer with BowX−BowY≠0 typically has a combination of a paraboloid (bow) deformation and a saddle-shape deformation (also referred to as simply a saddle deformation herein). For a purely saddle deformation, BowX=−BowY. Table 1 illustrates an example evolution of a wafer deformation during stress mitigation.

TABLE 1
Example stress mitigation with back side stress-compensation film deposition

| | | | | SCL | Stress- |
|---|---|---|---|---|---|
| | Deformed | FS protective | SCL | protective | modulation |
| | wafer | film deposition | deposition | film | beam |
| Film thickness (nm) | | 385.0 | 666.5 | 100.0 | |
| Film stress (GPa) | | 0.0 | −3.0 | −0.4 | |
| BowX (μm) | −100 | −100 | 1108 | 1133 | 652 |
| BowY (μm) | 300 | 300 | 1508 | 1533 | 804 |
| BowX − BowY | −400 | −400 | −400 | −400 | −152 |

The second column indicates deformation parameters of an example deformed wafer (e.g., a wafer with some features deposited thereon). In particular, the wafer has both the paraboloid deformation and the saddle deformation. A stress-free SiN front side (FS) protective film of thickness 385 nm is then deposited (or otherwise formed) on the wafer without changing the wafer's deformation (the third column in Table 1). An SCL of thickness 665.5 nm is then deposited on the back side of the wafer. The amount of stress in the SCL can be controlled (e.g., by controlling physical and/or chemical conditions in the deposition chamber used for depositing the SCL). In the illustrative example of Table 1 (the fourth column), the SCL—after deposition on the wafer—has compressive stress of −3.0 GPa. This causes the deformation of the wafer to increase to BowX=1108 μm, BowY=1533 μm, with both BowX and BowY being positive now. The SCL is then protected with a 100 nm SiO₂ film having compressive stress of −0.4 GPA, which causes a minor change in BowX and BowY (the fifth column). Application of the stress-modulation beam (as indicated with the sixth column in Table 1), reduces BowX and BowY as well as the difference BowX−BowY, which indicates that the amount of the saddle deformation has decreased.

Reduction in the saddle deformation improves accuracy of feature manufacturing operations. This improvement, however, comes at a cost of large intermediate deformations—in excess of 1.1 mm and 1.5 mm along the X-axis and Y-axis, respectively, occurring after the SCL deposition/protection operations. Deformations in excess of 1 mm (or some other similar value) can be detrimental for accuracy of wafer handling and/or other operations that are not explicitly referenced throughout this disclosure. On the other hand, limiting the amount of the intermediate deformation—e.g., by reducing the thickness of the SCL or the amount of stress in the SCL—may cause stress-modulation beam irradiation to be less effective. More specifically, an SCL with less stress or a smaller thickness may lack sufficient stiffness or volume to significantly reduce saddle deformation BowX−BowY (−0.4 mm in this example) when the wafer is subjected to the beam.

Aspects and embodiments of the present disclosure address these and other challenges of the modern semiconductor manufacturing technology by providing for systems and techniques that mitigate wafer deformations that occur in the course of intermediate processing of wafers. In some embodiments of the present disclosure, a protective film deposited on top of a stack of features—with suitably chosen non-zero stress—can serve as an additional mechanism for controlling stress and deformation of the wafers. For the purpose of nomenclature and ease of reading, the layers used for stress management on the front side of the wafer are referred to as protective films whereas the term SCL is used to refer to the layers deposited on the back side of the wafer, even though both the SCL(s) and protective film(s) are used for stress management.

The disclosed embodiments can be applied to improving chucking of any “wafer” or “substrate,” which refers to any material capable of supporting one or more films, masks, photoresists, layers, etc., that are deposited, formed, etched, or otherwise processed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. This includes bonded wafers where wafers can have underlayers formed. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

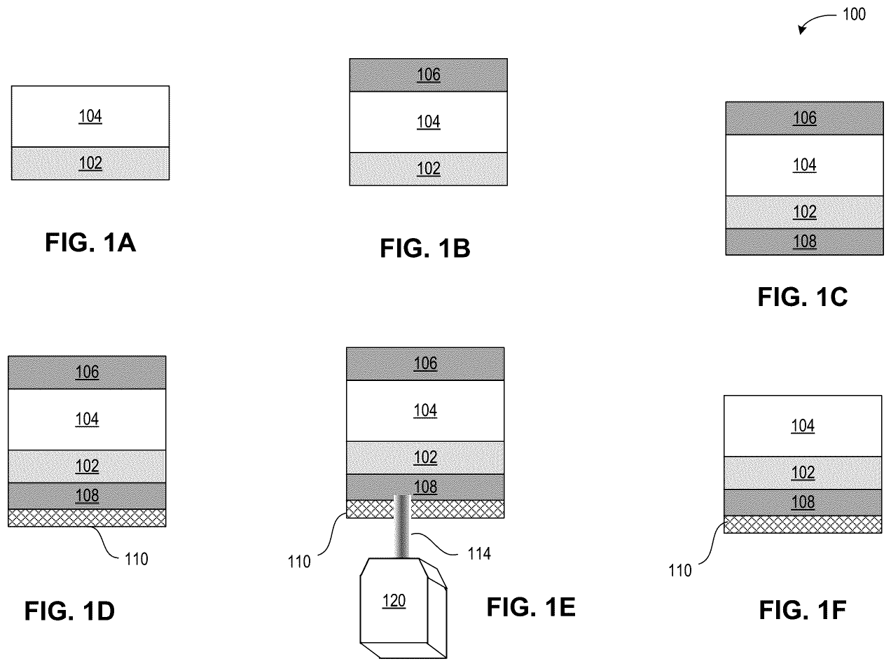

FIGS. 1A-1F illustrate schematically a process 100 of mitigating low-to-moderate saddle deformations in wafer processing using both front side protective films and back side stress-compensation layers, according to at least one embodiment. Table 2 illustrates parameters of one example stress mitigation, in accordance with process 100 of FIGS. 1A-1F. The stress mitigation process 100 is further illustrated with Table 2 listing example process parameters for the same wafer as illustrated above with Table 1 for the legacy stress mitigation.

TABLE 2
Example stress mitigation with a front side protective
film and a back side stress-compensation layer

| | | | | SCL | Stress- |
|---|---|---|---|---|---|
| | Deformed | FS protective | SCL | protective | modulation |
| | wafer | film deposition | deposition | film | beam |
| Film thickness (nm) | | 385.0 | 666.5 | 100.0 | |
| Film stress (GPa) | | −3.0 | −3.0 | −0.4 | |
| BowX (μm) | −100 | −798 | 410 | 435 | −46 |
| BowY (μm) | 300 | −398 | 810 | 835 | 106 |
| BowX − BowY | −400 | −400 | −400 | −400 | −152 |

As shown in FIG. 1A, a stack of features 104 can be grown (or deposited) on a wafer 102, a portion of which is shown schematically. Features 104 can include a stack of alternating O and N layers (e.g., three or more periodically repeated layers) or any other suitable features. It should be understood that FIGS. 1A-1E may not be to scale and that the thickness of the wafer 102 can significantly exceed the height of the stack of features 104. For example, a height of the wafer 102 can be of the order of 0.5-1 mm and the height of features 104 can be of the order of 10 μm.

As shown in FIG. 1B, a protective film 106 can be deposited (or otherwise formed) on top of features 104. Protective film 106 can be a SiN layer or a layer of some other material. The protective film 106 can have a stress and thickness selected such that, together with an SCL deposited on the back side, the deformation BowX and BowY remain within a certain target deformation interval, e.g., [−1 mm, 1 mm] or some other interval. In some embodiments, stress in protective film 106 can be controlled (e.g., by controlling the process conditions of protective film 106 deposition) within a stress interval [−σ₁, σ₂], e.g., [−3.3 GPa, +1.6 GPa], in one example non-limiting embodiment. As indicated in the third column in Table 2, protective film 106 of thickness 385 nm and compressive stress of −3.0 GPa can be deposited. This changes the wafer's deformation to BowX=−798 μm, BowY=−398 μm (reversing the sign of the average bow of the wafer).

As shown in FIG. 1C, an SCL 108 (of thickness 665.5 nm) is then deposited on the back side of wafer 102. The material, thickness, amount of stress in the SCL 108 can be selected and controlled to reverse the sign of deformation of the wafer, while still maintaining the wafer's deformation BowX, BowY to within the target deformation interval. For example (the fourth column in Table 2), compressive stress of −3.0 GPa changes the wafer's deformation to BowX=410 μm, BowY=810 μm.

As shown in FIG. 1D, SCL 108 can be covered, e.g., with an SCL protective film 110, which can be a 100 nm SiO₂ film (as indicated in the fifth column in Table 2) or a film of some other material. The SCL protective film 110 can cause some minor changes in BowX and BowY (which increase to 435 μm and 835 μm, respectively). The SCL protective film 110 can be deposited to protect the backside SCL 108 during the removal of frontside protective layer 106, e.g., if substances used in the removal are capable of damaging SCL 108. On the other hand, if chemicals used in the removal of protective layer 106 cannot damage SCL 108, the SCL protective film 110 may not be deposited/formed. For instance, if the front side SiN protective layer 106 is to be removed by a wet etch process (e.g., using hot phosphoric acid), the SCL protective layer 108 made of SiO₂ can be used to prevent the SCL 102 from being etched during the wet etch process. On the other hand, if an O₂ ash-able protective layer 106 (e.g., an amorphous carbon layer) is removed using oxygen gas, the SCL protective layer 110 does not have to be deposited (since the oxygen gas does not damage SCL 108 made of SiN).

As shown in FIG. 1E, a stress-modulation beam 114 can then be applied to SCL 108 and/or SCL protective film 110 that delivers a position-dependent dose of particles (e.g., ions, electrons, or photons) n(X, Y). Stress-modulation beam 114 can be generated by a suitable collimating and focusing column 120. Although, for the sake of conciseness, the stress-modulation beam 114 is shown in FIG. 1E as being directed upwards, in embodiments the stress-modulation beam 114 can have other directions. For instance, the wafer 102 (and various deposited films and layers) can be flipped upside down, with the stress-modulation beam 114 directed downwards. In this configuration, the stress-modulation beam 114 can be applied to the protective film 106 or other layers from the opposite side. This can be achieved by using an electrostatic chuck or some other end effector engaging the protective film 106 (not shown in FIG. 1E). Additionally, the stress-modulation beam 114 can be directed horizontally, with the wafer 102 (and various deposited films and layers) held vertically or held at various angles to the horizontal.

Application of stress-modulation beam 114 causes stress in the structure that includes wafer 102, features 104, protective film 106, SCL 108, and SCL protective film to decrease, resulting in the flattening of the structure, including reduced saddle deformation, e.g., as illustrated in the last column in Table 2, to BowX=−46 μm and BowY=106 μm with the remaining saddle deformation BowX−BowY=−152 μm being the same as in the example of Table 1. After stress-modification of the saddle deformation, the protective film 106 can be removed resulting in a structure shown in FIG. 1F.

Although in the examples of FIGS. 1A-1F protective film 106 and SCL protective film 108 are formed to facilitate handling of wafers with end effectors and/or processing of wafers on the chuck or pedestal, in some embodiments, handling and processing of wafers may be performed by gripping the wafer edges without touching the wafer's frontside and/or backside. In such instances, protective film 106 and/or SCL protective layer 110 may not be formed.

The operations disclosed in conjunction with FIGS. 1A-1F ensure that the wafer deformation remains within a target deformation interval even for intermediate operations, provided that the amount of saddle deformation is not too strong. Since mitigation of large saddle deformations may call for use of thicker SCL 108 and protective film 106, deposition of a thick protective film 106 and SCL 108 can cause large swings of the wafer's deformation, e.g., as illustrated in Table 3 for a wafer with a larger BowX−BowY=−700 μm.

TABLE 3
Example stress mitigation with with a front side protective film and
a back side stress-compensation layer for a high saddle deformation

| | | | | SCL | Stress- |
|---|---|---|---|---|---|
| | Deformed | FS protective | SCL | protective | modulation |
| | wafer | film deposition | deposition | film | beam |
| Film thickness (nm) | | 845.0 | 1400.0 | 100.0 | |
| Film stress (GPa) | | −3.0 | −3.0 | −0.4 | |
| BowX (μm) | −100 | −1632 | 906 | 930 | −78 |
| BowY (μm) | 600 | −932 | 1606 | 1630 | 101 |
| BowX − BowY | −700 | −700 | −700 | −700 | −179 |

For example, the magnitude of BowX increases to (negative) 1632 μm and BowY similarly increases to 1630 μm, both values exceeding the target interval for intermediate deformations.

In some embodiments, to dampen the swings of the wafer's deformation during intermediate operations of stress mitigation, multiple protective films 106 and/or multiple SCLs 108 can be deposited iteratively, with thinner slices of the films/layers deposited one after another.

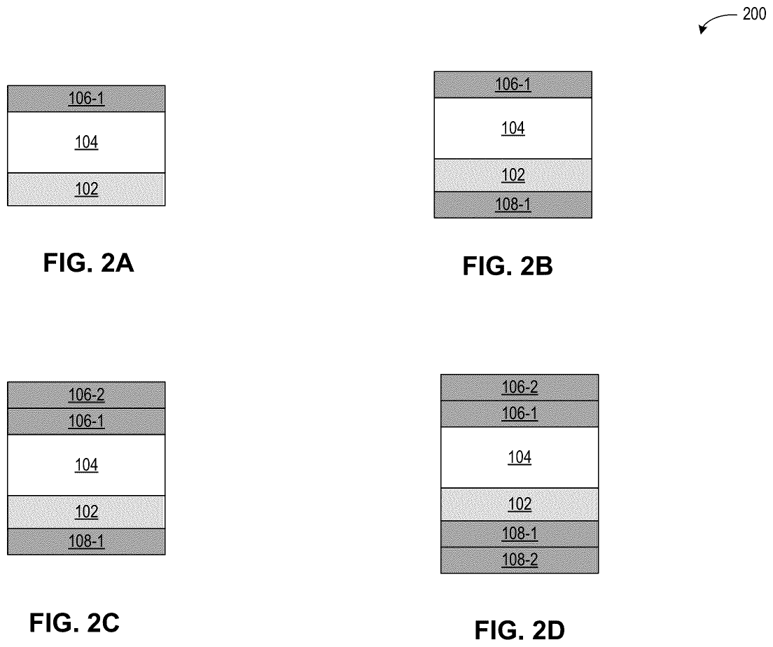

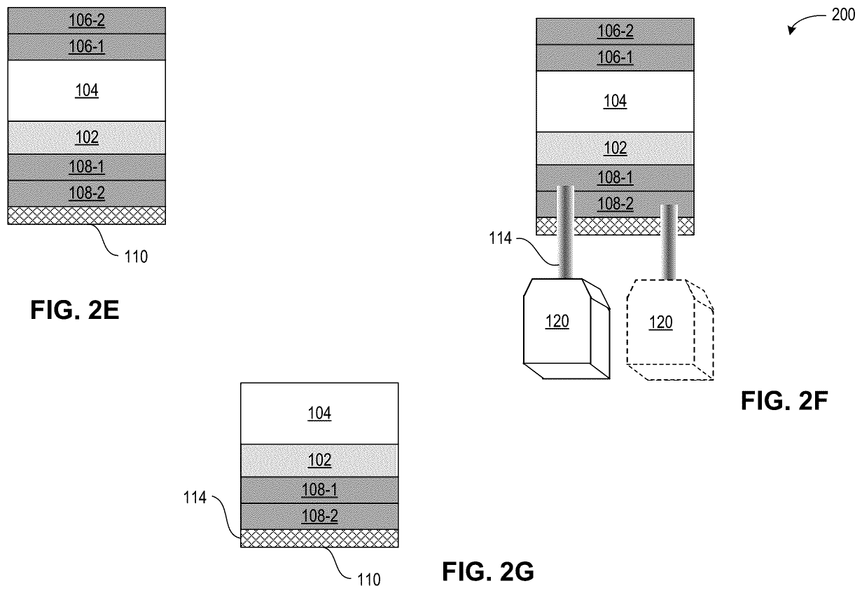

FIGS. 2A-2G illustrate schematically a process 200 of mitigating moderate-to-high saddle deformations in wafer processing using iterative front side protective film and back side SCL deposition, according to at least one embodiment. Table 4 illustrates parameters of one such example stress mitigation, in accordance with process 200 of FIGS. 2A-2G. The stress mitigation illustrated with Table 4 is performed for the same wafer as illustrated above with Table 3 for operations that do not involve iterative depositions.

TABLE 4
Example stress mitigation with multiple front side protection films and
and back side stress-compensation layers for a high saddle deformation

| | | | | | SCL- | SCL | Stress- |
|---|---|---|---|---|---|---|---|
| | Deformed | FS. film-1 | SCL- | FS. film-2 | 2 | protective | modulation |
| | wafer | deposition | 1 dep. | deposition | dep. | film | beam |
| Film | | 490.0 | 700.0 | 700.0 | 700.0 | 100.0 | |
| thickness | | | | | | | |
| (nm) | | | | | | | |
| Film | | −3.0 | −3.0 | −3.0 | −3.0 | −0.4 | |
| stress | | | | | | | |
| (GPa) | | | | | | | |
| BowX | −100 | −988 | 281 | −988 | 281 | 305 | −704 |
| (μm) | | | | | | | |
| BowY | 600 | −288 | 981 | −288 | 981 | 905 | −525 |
| (μm) | | | | | | | |
| BowX − | −700 | −700 | −700 | −700 | −179 | −700 | −179 |
| BowY | | | | | | | |

As shown in FIG. 2A, a first protective film 106-1 (e.g., a layer of SiN or some other material) can be deposited (or otherwise formed) on features 104. As shown in FIG. 2B, a first SCL 108-1 can be deposited on the back side of wafer 102. As shown in FIG. 2C, a second protective film 106-2 can be deposited on the first protective film 106-1. The second protective film 106-2 can be made of the same material as a material of the first protective film 106-1 or a different material. As shown in FIG. 2D, a second SCL 108-2 can be deposited on the first SCL 108-1. As shown in FIG. 2E, the second SCL 108-2 can be covered with an SCL protective film 110, e.g., a SiO₂ film of film of some other material. As shown in FIG. 2F, stress-modulation beam 114 can then be applied to the first SCL 108-1, the second SCL 108-2, and SCL protective film 110 by delivering position-dependent dose n(X, Y) of particles (e.g., ions, electrons, or photons). After stress-modification of the saddle deformation, as shown in FIG. 2G, the protective films 106-1 and 106-2 can be removed, e.g., using chemical mechanical polishing or some other suitable operations.

Table 4 illustrates example parameters of various protective and stress-compensation layers, such as thickness of various layers and the amount (and sign) of stress in the layers. Table 4 further indicates how wafer deformation changes after each layer deposition. In particular, iterative deposition illustrated in FIGS. 2A-2G reduces the swings of the wafer deformation after individual depositions. For example, both BowX and BowY remain within the target interval [−1000 μm, 1000 μm] of deformations.

Although each of the front side protective films 106-n and back side deposited SCLs 108-n is split into two portions (slices), the number of portions need not be so limited. In some embodiments, a number N=1, 2, . . . of portions of protective film 106 can be different from a number M=1, 2, . . . of portions of SCL 108. The numbers N and M can be determined, as part of optimization/modeling of wafer deformation, prior to the implementation of the stress mitigation processing, e.g., based on specific amounts of the saddle deformation BowX−BowY as well as on individual values BowX and BowY. In particular, for a given target range of deformations [−h₁, +h₂], the numbers N and M can be larger for larger values of |BowX−BowY|.

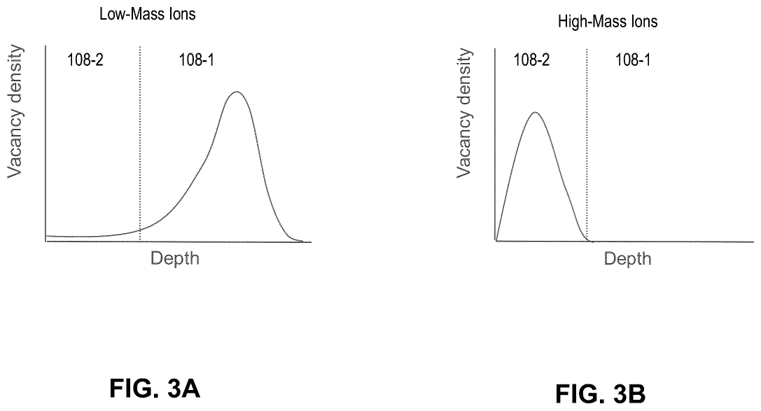

Application of stress-modulation beam 114 after all of the first SCL 108-1, the second SCL 108-2, and SCL protective film 110 are deposited can be performed (as illustrated in FIG. 2F) by controlling the energy and/or mass of the particles of the beam, so that the beam delivers a controlled dose of particles to different depths of the SCLs 108-n and SCL protective film 110. FIGS. 3A-3B illustrate schematic distribution of vacancies created by ions of different masses irradiating a stress-compensation layer having multiple portions, according to at least one embodiment. As illustrated in FIG. 3A, low-mass ions having maximum penetration inside the first SCL film 108-1 may be used to modify stress in the first SCL 108-1 without significantly affecting stress in the second SCL 108-2. As illustrated in FIG. 3B, high-mass ions having maximum penetration inside the second SCL 108-2 may be used to modify stress in the second SCL 108-2 without significantly affecting stress in the first SCL 108-1.

The embodiment of FIG. 2F (with SCLs irradiated after multiple, e.g., all, SCLs are deposited) is economical from the standpoint of minimizing a number of wafer handling operations, as the wafer has to be removed from a deposition chamber only once for a single session of beam irradiation.

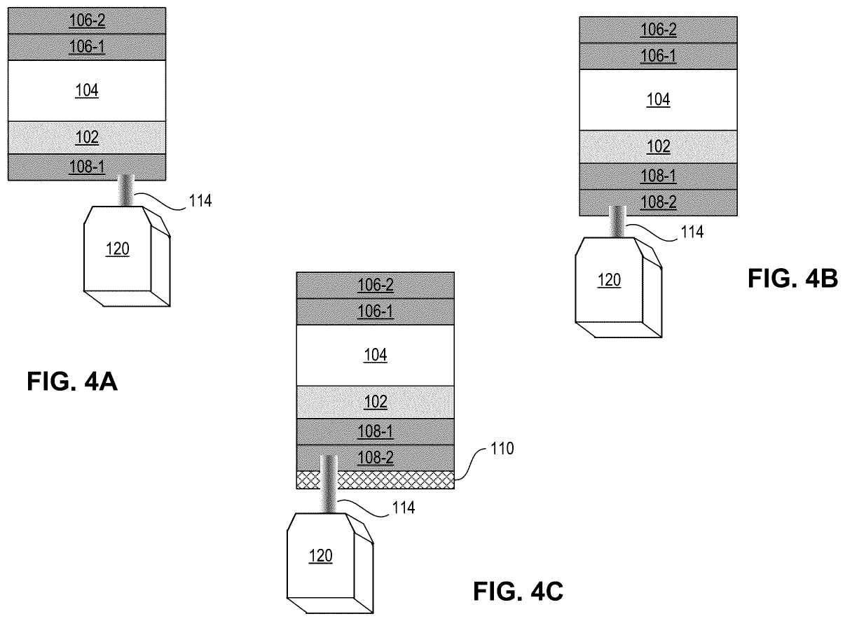

FIGS. 4A-4C illustrate an example processing of a wafer using a stress-modulation beam as part of mitigation of moderate-to-high saddle deformations in wafer processing, according to at least one embodiment. Embodiments of FIGS. 4A-4C, allow additional control over the amount of stress mitigation in each of the SCLs 108-n and the SCL protective film 110 achieved by applying stress-modulation beam 114 following deposition/formation of individual layers. For example, stress-modulation beam 114 can be applied (FIG. 4A) to the first SCL 108-1 after the first SCL 108-1 is deposited and prior to deposition of the second SCL 108-2. Similarly, stress-modulation beam 114 can be applied (FIG. 4B) to the second SCL 108-2 after the second SCL 108-2 is deposited and prior to deposition of the SCL protective film 110. 108-2. In some embodiments, stress-modulation beam 114 can be applied to one or more SCLs, e.g., the second SCL 108-2 (as illustrated in FIG. 4C), after the last SCL and the SCL protective film 110 have been deposited and the wafer removed from a deposition chamber. Individual irradiation of various layers can allow a finer control of stresses in those layers. Although FIG. 2F illustrates joint irradiation of all layers deposited on the back side of the wafer and FIGS. 4A-4C illustrate individual irradiation of each layer, any number of layers can be jointly irradiated. For example, both the first SCL 108-1 and the second SCL 108-1 can be irradiated together while additional SCL(s) (not shown in FIGS. 4A-4C) are irradiated individually. In some embodiments, the SCL protective film 110 is not irradiated (e.g., no operation of FIG. 4C is performed).

In some instances, a high level of stress in the front side protective film 106 (temporarily compensated with an opposite-sign stress in the SCL 108) can result in a significant bow deformation after the saddle stress mitigation (by the particle irradiation) and removal of the protective film 106. Even though a bow-like (paraboloid) deformation may be not as detrimental in device manufacturing as a saddle deformation, in some manufacturing processes it can be advantageous to also minimize (or reduce) the bow deformation. To maintain a low (or zero) stress in the protective film 106 while enabling mitigation of large saddle deformations BowX−BowY, multiple SCL portions can be deposited on the back side with alternating sign of stress, e.g., compressive/tensile/compressive/etc.

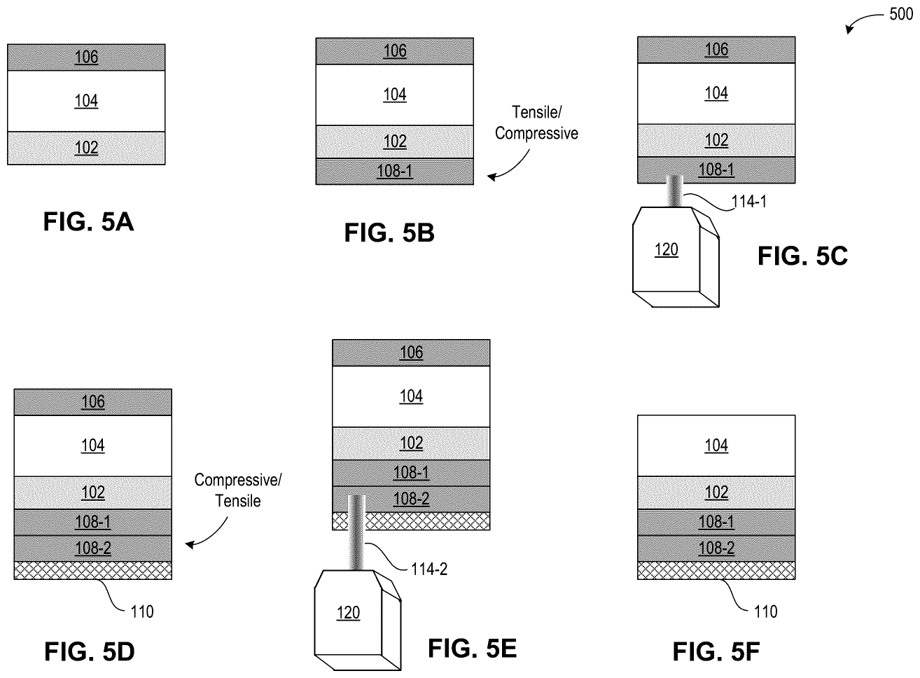

FIGS. 5A-5F illustrate schematically a process 500 of mitigating a wafer deformation using back side stress-compensation layers with alternating stress, according to at least one embodiment. Table 5 illustrates parameters of one example stress mitigation, in accordance with process 500 of FIGS. 5A-5F. The stress mitigation illustrated with Table 4 is performed for the same wafer (as indicated with the second column in Table 5) as illustrated above with Table 1 and Table 2.

TABLE 5
Example stress mitigation with multiple stress-compensation layers of alternating stress

| | Deformed | FS. prot. | | | | SCL prot. | | FS film |
|---|---|---|---|---|---|---|---|---|
| | wafer | film | SCL-1 | SMB-1 | SCL-2 | film | SMB-2 | removal |
| Film | | 385.0 | 666.4 | | 333.2 | 100.0 | | |
| thickness | | | | | | | | |
| (nm) | | | | | | | | |
| Film | | 0.3 | 1.5 | | −3.0 | −0.4 | | |
| stress | | | | | | | | |
| (GPa) | | | | | | | | |
| BowX | −100 | −30 | −634 | −270 | 334 | 358 | 118 | 48 |
| (μm) | | | | | | | | |
| BowY | 300 | 370 | −234 | 6 | 610 | 634 | 270 | 200 |
| (μm) | | | | | | | | |
| BowX − | −400 | −400 | −400 | −276 | −276 | −276 | −152 | −152 |
| BowY | | | | | | | | |

As shown in FIG. 5A, protective film 106 can be deposited on features 104. Protective layer 106 can have a moderate or low amount of stress, e.g., tensile stress +0.3 GPa (with reference to the third column in Table 5). This changes the wafer's deformation (uniformly by +70 μm along both directions) to BowX=−30 μm, BowY=370 μm.

As shown in FIG. 5B, a first SCL 108-1 of thickness 666.4 nm is deposited on the back side of wafer 102. In the illustrative example (the fourth column in Table 5), the first SCL 108-1 has tensile stress +1.5 GPa and changes the wafer's deformation to

$$BowX = - 634 μm , BowY = - 234 μm .$$

As shown in FIG. 5C, a first stress-modulation beam (SMB-1) 114-1 can be applied to the first SCL 108-1. The first stress-modulation beam 114 can deliver a position-dependent dose of particles n₁ (X, Y) determined (using simulations, modeling, and/or other techniques) to reduce the amount of saddle deformation and flatten the wafer structure. In the illustrative example (the fifth column in Table 5), saddle deformation is reduced from

$$BowX - BowY = - 400 μm to BowX - BowY = - 276 μm .$$

As shown in FIG. 5D, after stress-modification of the saddle deformation, a second SCL 108-2 can be deposited on the first SCL 108-1. The second SCL 108-2 can have stress of the opposite sign than the first SCL 108-2. More specifically, the second SCL 108-2 can have tensile stress if the first SCL 108-1 has compressive stress and vice versa. The material of the second SCL 108-2 can be the same or different from the material of the first SCL 108-1. In the illustrative example (the sixth column in Table 5), the second SCL 108-2 has thickness 333.2 nm and compressive stress of −3.0 GPa that changes the wafer's deformation to BowX=334 μm, BowY=610 μm. As further illustrated in FIG. 5D (and the seventh column in Table 5), SCL protective film 110 can be formed on the second SCL 108-2, which can cause a small change the wafer's deformation (given a relatively small thickness of the SCL protective film 110, e.g., 100 nm).

As shown in FIG. 5E, a second stress-modulation beam (SMB-2) 114-2 can be applied to the second SCL 108-2. The second stress-modulation beam 114-2 can deliver a different position-dependent dose of particles n₂ (X, Y) determined to further reduce the amount of saddle deformation. In the illustrative example (the eighth column in Table 5), saddle deformation is reduced from BowX−BowY=−276 μm to BowX−BowY=−152 μm.

The front side protective film 106 can then be removed resulting in a structure shown in FIG. 5F. In the illustrative example (the final column in Table 5), the removal of the protective film causes the wafer's deformation to change uniformly by a small amount of −70 μm along both directions (which is the inverse of the deformation caused by deposition of the protective film 106).

Although deposition of two SCLs of alternating (tensile/compressive) stresses is illustrated in FIGS. 5A-5F for conciseness and ease of viewing, the number of used SCLs need not be limited. Any other number, e.g., three, four, etc. of SCLs can similarly be deployed. In some embodiments, multiple front-side protective films 106 of alternating stresses can also be deposited (and removed after completion of the stress-modification processing).

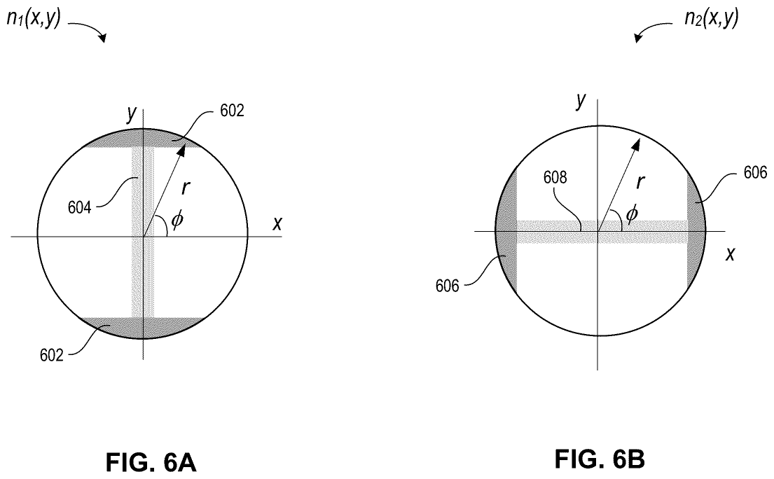

FIGS. 6A-6B illustrate example position-dependent doses of particles delivered by a stress-modulation beam to stress-compensation layers deposited on wafers to mitigate a saddle deformation of the wafer, according to at least one embodiment. Particles can include ions, electrons, or photons, or any combination thereof. For the sake of specificity, the subsequent description refers to ions, but doses of other particles can be configured in a similar way. In one example embodiment, as illustrated in FIG. 6A, the first position-dependent dose of particles n₁ (X, Y) can include edge implants 602 in which ion implantation dose is applied within a certain edge area of an SCL (e.g., the first SCL 108-1).

In some embodiments, a width of the edge implant can be within d≈1-10 mm. In some embodiments, the width of the edge implant can be less than 1 mm or more than 10 mm. In some embodiments, the width of the edge implant can be at or below 10% of a diameter of the wafer or some other fraction of the diameter (e.g., 5%, 20%, etc.). In some embodiments, dose n₁ (X, Y) can include one or more longitudinal implants 604. Edge implants 602 and longitudinal implants 604 can have different ion implant density, e.g., edge implants 602 can have a higher ion implant density compared with longitudinal implants 604. In one example embodiment, as illustrated in FIG. 6B, the second position-dependent dose of particles n₂ (X, Y) can include edge implants 606 in which ion implantation dose is applied within a certain edge area of the second SCL 108-2. In some embodiments, the second dose n₂ (X, Y) can further include longitudinal implants 608. In some embodiments, the width of longitudinal implants 604 and 608 can be within d≈0-300 mm. Edge implants 606 and longitudinal implants 608 of the second dose n₂ (X, Y) can be rotated (in the X-Y plane of the wafer) relative to edge implants 602 and longitudinal implants 604 of the first dose n₁ (X, Y) by an angle of (approximately) 90 degrees (or −90 degrees).

In some embodiments, the doses of stress-modulation beams delivered to the SCL may be patterned along one or both spatial directions. For example, a protective grating may be deposited or otherwise formed on the SCL such that some regions of the SCL are exposed more (corresponding to grooves or valley of the protective grating) than other regions (e.g., shielded by ridges of the protective grating). Correspondingly, elastic properties of the SCL may be modified more substantially along one direction than along the other directions, which may be used to correct cylindrical and/or saddle deformations. After irradiation of the SCL with the stress-modulation beam, the protective grating can be removed. In some embodiments, focused beams of particles and/or photons may be used for spatial modulation of doses of radiation without application of protective gratings. In some embodiments, a diffraction pattern may be used in conjunction with a photon stress-modulation beam to expose the SCL to spatially-varying doses of photons.

In some embodiments, the first dose n₁ (X, Y) can be delivered to an SCL having a tensile stress and the second dose n₂ (X, Y) can be delivered to an SCL having a compressive stress, or vice versa.

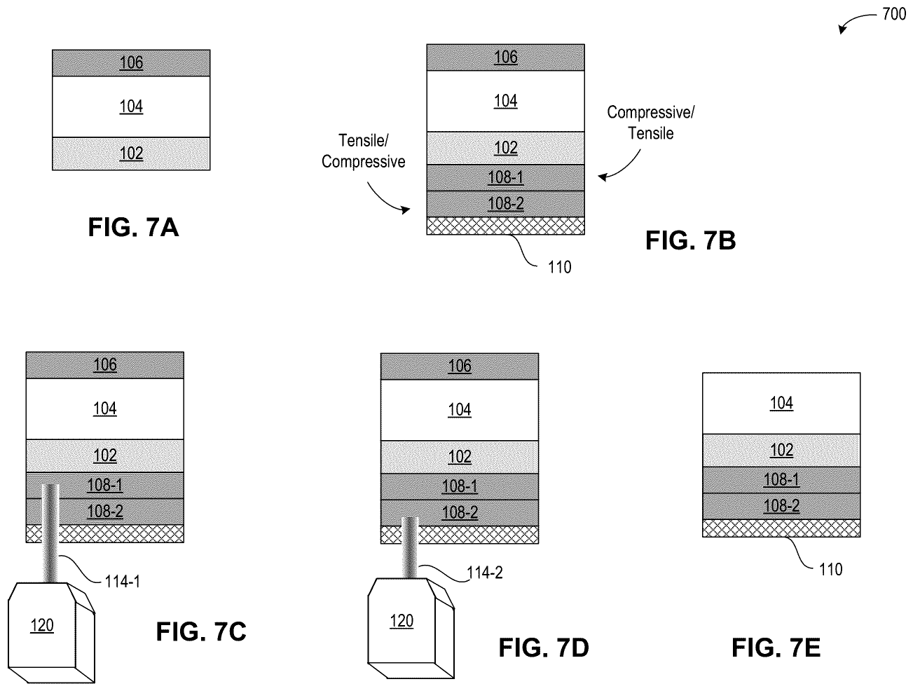

FIGS. 7A-7E illustrate schematically another example process 700 of mitigating a wafer deformation using back side stress-compensation films of alternating stress, according to at least one embodiment. As illustrated, after deposition of a front side protective film 106 (FIG. 7A), multiple SCLs with alternating stress, e.g., SCL 108-1, SCL 108-2, etc., can be deposited on the wafer's back side (FIG. 7B). In some embodiments, SCL protective film 110 can also be formed to protect the SCLs. Subsequently, stress-modulation beam can be applied to various deposited SCLs, e.g., stress in SCL 108-1 can be mitigated with stress-modulation beam 114-1 (FIG. 7C) stress in SCL 108-2 can be mitigated with stress-modulation beam 114-2 (FIG. 7D), and so on, if more than two SCLs are being used. The two (or more) stress-modulation beams 114-1, 114-2, etc., can use different species of particles (e.g., ions of different types), different energies, penetrations depths, and/or the like, e.g., as disclosed in conjunction with FIGS. 6A-6B above. After the stress-modulation beam processing of the SCLs is complete, front side protective film 106 can be removed (FIG. 7E).

In some embodiments, the stresses in various layers (e.g., front side protective film(s) 106, SCLs 108-n, SCL protective film 110, etc.), the thickness of those layers, the implantation doses (maps) n₁ (X, Y), n₂ (X, Y), etc., to be deposited into the individual layers can be determined using modeling, simulations, and/or other techniques.

In some embodiments, Monte Carlo simulations can be used. The Monte Carlo simulations can be performed for one or more films made of the actual material(s) used in film deposition and having a specific thickness d (or multiple thicknesses d₁, d₂, etc.) An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to the film(s), SCL(s), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of films/layers, angles of particle incidence on the films, and/or the like.

In some embodiments, the implantation maps n₁ (X, Y), n₂ (X, Y), etc., can be computed using an influence function G(\vec{r}; \vec{r}′) that characterizes a response (e.g., deformation) at a point \vec{r}=(X, Y), of the wafer as caused by a point-like force applied at another point \vec{r}′ of the wafer. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, wafer deformation h(\vec{r})=h_{quad}(\vec{r})+hᵣₑₛ(\vec{r}) can be represented(decomposed) as a combination of a quadratic h_{quad}(\vec{r}) and residual (non-quadratic) hᵣₑₛ(\vec{r}) contributions. The quadratic deformation can include a parabolic (paraboloid) part hₚₐᵣ(\vec{r}), which has the complete axial symmetry, and a saddle part h_{saddle}(\vec{r}). The thickness d of a film can be computed (or empirically determined) in such a way that the film is to apply a desired target stress to the wafer. To eliminate a non-uniform saddle deformation, the film can be of such thickness/material that turns the saddle deformation into a cylindrical deformation having a definite sign throughout the area of the wafer. The uniform-sign cylindrical deformation (as well as a residual higher-order non-quadratic deformation) can then be mitigated with irradiation by a stress-modulation beam. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of the film (e.g., type and thickness) while the remaining cylindrical deformation (and the higher-order residual deformation) can be addressed by appropriately selected ion or photon irradiation doses n₁ (X, Y), n₂ (X, Y), etc.

In some embodiments, mitigation of a cylindrical deformation or a saddle deformation can include identifying principal axes (directions) of the cylinder/saddle and a magnitude of the cylindric/saddle deformation and directing the stress-modulation beam into appropriately selected edge regions of the hard mask. For example, individual edge regions to which the beam is directed can have a width that is at or below 30% of a diameter of the wafer. Residual higher-order (ripple) deformations can then be mitigated with further irradiation into the area of the mask.

Some of these techniques will now be described in more detail. In one embodiment, a vertical profile of wafer deformation z=h(\vec{r}) can be measured using optical metrology techniques. For example, an interferogram of the profile h(\vec{r}) can be obtained using optical interferometry measurements. The wafer profile h(\vec{r}) can then be represented via a number of parameters that qualitatively and quantitatively characterize geometry of the wafer deformation. In some embodiments, a set of Zernike (or a similar set of) polynomials may be used to represent the wafer profile,

$$h ( \vec{r} ) = {\sum }_{j} {A}_{j} {Z}_{j} ( \vec{r} ) ,$$

where the planar radius-vector \vec{r}=(r, ϕ) may be represented as the radial coordinate r and the polar angle ϕ within the (average) plane of the wafer. Consecutive coefficients A₁, A₂, A₃, A₄ . . . represent weights of specific geometric features (elemental deformations) of the wafer described by the corresponding Zernike polynomials Z₁ (r, ϕ), Z₂ (r, ϕ), Z₃ (r, ϕ), Z₄ (r, ϕ), . . . (Herein, the Noll indexing scheme for the Zernike polynomials is being referenced.) The first three coefficients are of less interest as they describe a uniform shift of the wafer (coefficient A₁, associated with the Z₁ (r, ¢)=1 polynomial), a deformation-free x-tilt that amounts to a rotation around the y-axis (coefficient A₂, associated with the Z₂ (r, ϕ)=2r cos ϕ polynomial), and a deformation-free x-tilt that amounts to a rotation around the x-axis (coefficient A₃, associated with the Z₃ (r, ϕ)=2r sin ϕ polynomial) that can be eliminated by a realignment of the coordinate axes. The fourth coefficient A₄ is associated with Z₄(r, ϕ)=\sqrt{3}(2r²−1) and characterizes an isotropic paraboloid deformation (“bow”). The fifth A₅ and the sixth A₆ coefficients are associated with Z₅(r, ϕ)=\sqrt{6} r² sin 2ϕ and Z₆(r, ϕ)=\sqrt{6} r² cos 2ϕ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation h(r, ϕ) along the radial direction, along the azimuthal direction, or both and collectively represent a residual deformation, hᵣₑₛ(r, ϕ)=h(r, ϕ)−Σⱼ₌₄⁶AⱼZⱼ(r, ϕ). FIG. 8 illustrates an example Zernike polynomial decomposition 800 of one actual deformation h(r, ϕ) (top left) of a wafer, in arbitrary units, into a paraboloid bow deformation A₄Z₄ (r, ϕ) (top right), a saddle deformation A₅Z₅ (r, ϕ)+A₆Z₆ (r, ϕ) (bottom left), and a residual deformation, hᵣₑₛ(r, ϕ) (bottom right), according to at least one embodiment.

In some embodiments, a vertical profile of wafer deformation z=h(\vec{r}) can be measured using optical metrology (e.g., optical interferometry) techniques. In some embodiments, wafer deformation z=h(\vec{r}) can be measured after a stack of layers/films is deposited on the wafer. The wafer profile h(\vec{r}) can then be represented via a number of parameters that qualitatively and quantitatively characterize geometry of the wafer deformation, e.g., a set of Zernike (or a similar set of) polynomials, h(\vec{r})=ΣⱼAⱼZⱼ(\vec{r}). Consecutive coefficients A₁, A₂, A₃, A₄ . . . represent weights of specific geometric features (elemental deformations) of the wafer described by the corresponding Zernike polynomials Zⱼ(\vec{r}). In some embodiments, a material of hard mask can be selected based on the sign of a paraboloid bow coefficient A₄. In some embodiments, selection of a thickness d of an SCL can be made based on a value of the paraboloid bow coefficient A₄. The SCL can also serve as a stress-modification layer. The SCL can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). Thickness d of the SCL can be selected to overcorrect the wafer deformation to some degree. The overcorrection can be chosen in conjunction with a type of stress-modulation beam (e.g., ion implants, photons, electrons, etc.), a type of implant species, energy, and dose to ensure maximum effect from the stress mitigation. Stress in the combined structure of the wafer, films, etc., can then be modified by the stress-modulation beam that strikes one or more SCLs and change the physical structure of the SCL(s). Substitution defects and/or vacancies created by the beam mitigate (e.g., reduce) stress in the SCL(s) and can reduce the degree of stress overcorrection caused by the SCL deposition. This causes the wafer to flatten.

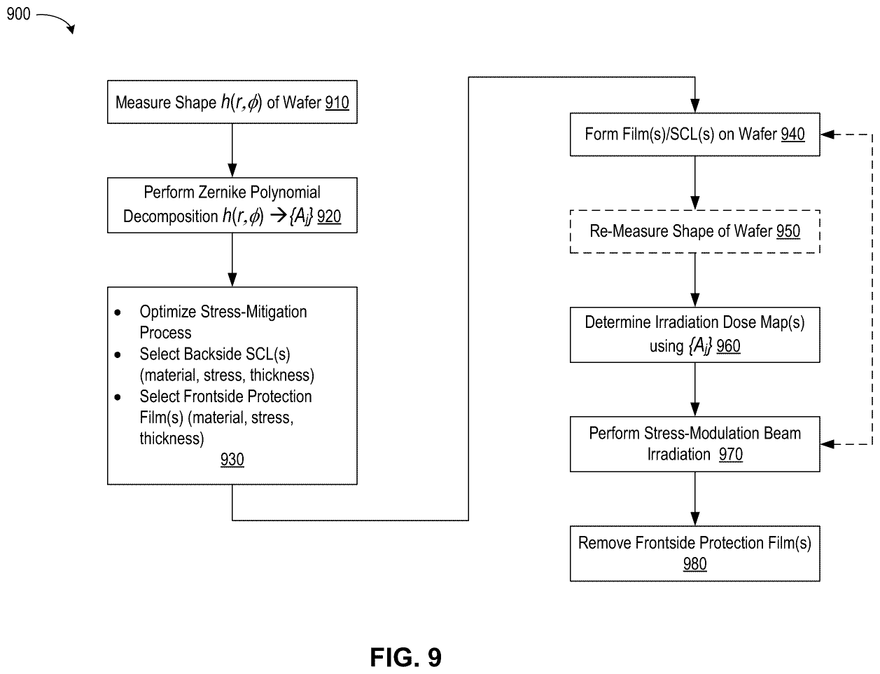

FIG. 9 is a flowchart illustrating an example method 900 of mitigation of wafer deformation using front side protection films and back side stress-compensation layers, in accordance with at least one embodiment. Method 900 can be performed to manufacture one or more semiconductor devices using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle wafers, e.g., moving wafers into and out of processing chambers. The transfer chamber can further be connected to a load-lock chamber (Front-End Interface) that can be coupled to one or more Front Opening Unified Pod carriers that hold bare wafers, processed wafers, partially processed wafers, and/or the like. Operations performed by the semiconductor manufacturing system, including any, some or all operations of method 900, can be performed responsive to instructions issued by a suitable computing device having a processing logic and memory to store the instructions.

Method 900 can include preparing a substrate (e.g., wafer 102), including but not limited to obtaining a bare substrate, preprocessing the bare substrate, e.g., polishing the substrate, removing stains and/or residue from the substrate, depositing one or more films/layers on the substrate, and/or performing any number of similar operations. For example, the features can include a layer of a conducting material, which can include interconnect circuitry, transistor, and/or the like. In some embodiments, the features can include oxygen layers, nitrogen layers, silicon layers, germanium layers, silicon-germanium alloy layers, and/or any other suitable layers. Various layers can be used as hosts of memory cells, transistors, separations between memory cells/transistors, and/or the like. At block 910, method 900 can include obtaining optical inspection data characterizing a profile of deformation of the substrate, e.g., measuring the shape of the substrate, e.g., a displacement of a surface (e.g., the top surface) of a substrate as a function of some in-plane coordinates, e.g., polar coordinates z=h(r, ϕ), Cartesian coordinates, z=h(x, y), or any other suitable coordinates.

At block 920, method 900 includes decomposing the determined shape (profile) over a suitable set of polynomials, e.g., Zernike polynomials, and obtaining a set of polynomial expansion coefficients, {Aⱼ}=(A₁, A₂, A₃), A₄, A₅, A₆, A₇, . . . , each coefficient in the set characterizing a degree of presence of a particular elemental geometric shape in the substrate's deformation.

At block 930, method 900 can include optimizing the stress-modification process. Operations of block 930 can include determining various characteristics of the back side SCL(s) and the front side protective films, including materials, amounts and signs (tensile or compressive) of stresses, thicknesses, and/or the like.

In some embodiments, operations of block 930 include identifying first characteristics of one or more protective films, the first characteristics including an amount of stress in each of the one or more protective films. In some embodiments, operations of block 930 further include identifying second characteristics of one or more stress-compensation layers (SCLs), the second characteristics including an amount of stress of each of the one or more SCLs. In some embodiments, identifying the first characteristics of one or more protective films and/or the second characteristics of one or more SCLs is based at least on the profile of deformation of the substrate (obtained at block 910). In some embodiments, identifying the first characteristics of one or more protective films or the second characteristics of one or more SCLs is based on the polynomial decomposition of the profile (obtained at block 920). In some embodiments, the first characteristics further includes a thickness of each of the one or more protective films, and the second characteristics further includes a thickness of each of the one or more SCLs. In some embodiments, the first characteristics and the second characteristics can be identified to maintain deformation of the substrate, to within a target range of deformations, when the one or more protective films and/or the one or more SCL are formed on the substrate (or one or more features deposited or otherwise formed on the substrate. In some embodiments, a first SCL of the one or more SCLs has a first stress and a second SCL of the one or more SCLs has a second stress, whose sign is opposite to a sign of the first stress.

In some embodiments, an optimization software operating on a computing device can evaluate the polynomial expansion coefficients, e.g., A₄, A₅, A₆, . . . , expansion coefficients or BowX, BowY deformations (which can be expressed via A₄, A₅, A₆), and can select one of the disclosed mitigation techniques, e.g., (i) single front side protective film/single back side SCL (disclosed in conjunction with FIGS. 1A-1F), (ii) multiple front side protective films/multiple back side SCLs (disclosed in conjunction with FIGS. 2A-2G), (iii) alternating back side SCLs (disclosed in conjunction with FIGS. 5A-5F and/or FIGS. 7A-7F), and/or the like. Optimization of the stress-modification process can further include selecting a protocol for applying one or more stress-modulation beams, e.g., selecting from application of a stress-modulation beam after all SCLs are deposited (as disclosed in conjunction with FIG. 2F, FIGS. 7C-7D), application of a stress-modulation beam after individual SCLs are deposited (as disclosed in conjunction with FIGS. 4A-4C, FIGS. 5C-5E), and/or some combination thereof. For example, selection of the protocol can include evaluating the size of the saddle deformation BowX−BowY and selecting a single front side protective film/single SCL in the instances of the saddle deformation being less than some (e.g., empirically set) first threshold and selecting multiple SCLs in the instance of the saddle deformation being larger than the first threshold. Similarly, the optimization can include estimating an amount of a bow change following the eventual removal of the front side protective film(s) and selecting higher-stress front side protective film(s) in the instances where the bow change is estimated to be less than a second threshold while selecting lower-stress front side protective film(s) with alternating-stress SCLs in the instances where the bow change is estimated to be more than a second threshold.

At block 940, method 900 can continue with forming various front side protectives film(s) and SCL(s) on the substrate, e.g., forming, on a front side of the substrate, the one or more protective films having the first characteristics and/or forming, on a back side of the substrate, the one or more SCLs having the second characteristics. In some embodiments, at least one SCL of the one or more SCLs is formed after forming a first protective film of the one or more protective films and before forming a second protective film of the one or more protective films.

At optional block 950, a new shape of the substrate with the deposited films/SCLs can be re-measured and the new expansion coefficients {Aⱼ} can be determined. Based on the new expansion coefficient, the stress-modification protocol can be adjusted. For example, additional films can be deposited (on either the front side or the back side or both) on the substrate.

At block 960, method 900 can include determining (e.g., computing using simulations) local dose maps for irradiation of the films/SCLs. In some embodiments, the dose maps can be computed based on the expansion coefficients A₅, A₆ (to compensate for the saddle deformation) or, equivalently, on BowX, BowY. In some embodiments, the dose maps can further be based on A₇, A₈, etc. (e.g., to compensate for a residual deformation).

At block 970, method 900 can continue with subjecting at least one SCL of the one or more SCLs to a stress-modulation beam (e.g., according to the computed irradiation doses) to reduce the amount of stress in the substrate/film(s)/SCL(s) structure and flatten the structure, e.g., causing a saddle deformation of the substrate to be reduced. The stress-modulation beam can include ions, photons, electrons, and/or any combination thereof. In some embodiments, operations of block 970 can include subjecting the one or more SCLs to the stress-modulation beam having first settings, the first settings including a first beam penetration depth, and subjecting the one or more SCLs to the stress-modulation beam having second settings, the second settings including a second beam penetration depth different from the first beam penetration depth. In some embodiments, operations of block 970 can include subjecting a first SCL of the one or more SCLs to the stress-modulation beam prior to forming a second SCL of the one or more SCLs. In some embodiments, operations of block 970 can include exposing the first SCL to a first spatial pattern of irradiation by the stress-modulation beam and exposing the second SCL to a second spatial pattern of irradiation by the stress-modulation beam, the second spatial pattern being different from the first spatial pattern. In some embodiments, the second spatial pattern can be, to a predetermined angle, relative to the first spatial pattern. In some embodiments, the predetermined angle can be approximately 90 degrees, in a clockwise direction or a counterclockwise direction, e.g., between 85 degrees and 95 degrees in the corresponding direction, between 80 degrees and 100 degrees in the corresponding direction, and/or the like. In some embodiments, the first spatial pattern includes a plurality of edge regions of the first SCL, wherein each of the plurality of edge regions of the SCL having a width that is at or below 30% of a diameter of the substrate.

At block 980, method 900 can include removing the front side protective film(s).

Although in the flowchart of FIG. 9, operations of block 970 (beam irradiation) are shown to follow operations of block 940 (film deposition), in some embodiments the corresponding operations can be interspaced (as indicated schematically with the dashed arrow), e.g., as disclosed in conjunction with FIGS. 4A-4C and FIGS. 5C-5E.

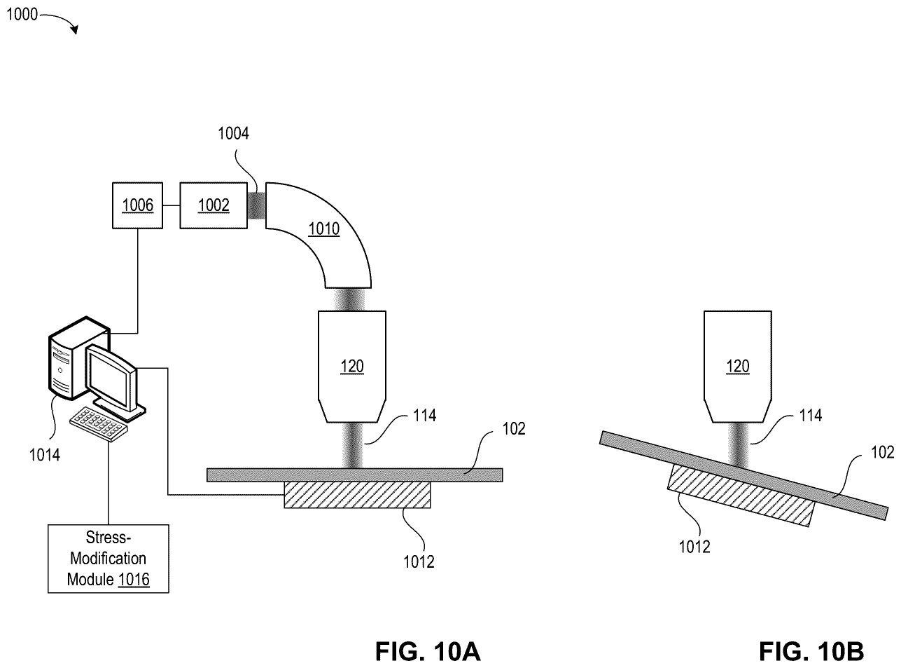

FIG. 10A illustrates schematically an irradiation system 1000 capable of performing irradiation of stress compensation layers, according to at least one embodiment. Irradiation system 1000 can include collimating and focusing column 120 of FIG. 1. Irradiation system 1000 can further include a beam source 1002 for producing a source beam 1004. Beam source 1002 can include a chamber for generating ions (e.g., a plasma chamber), a light source for generating photons (e.g., a laser, laser diode, lamp, etc.), a heated filament for producing electrons, and/or any other source for the particles of a type deployed in specific stress-modification techniques of the instant disclosure. Beam source 1002 can be powered by a power element 1006 and can include an extraction electrode assembly (not shown). Irradiation system 1000 can include a mass spectrometer 1010 (e.g., in the instances where beam source 1002 produces charged particles, such as electrons or ions) and a collimating and focusing column 120. Collimating and focusing column 120 can direct stress-modulation beam 114 to wafer 102 or any other substrate. Wafer 102 can be supported by a support stage 1012. In some embodiments, support stage 1012 and wafer 102 can remain stationary during irradiation of wafer 102 by stress-modulation beam 114 while components of irradiation system 1000 can be repositioned relative to wafer 102. In some embodiments, irradiation system 1000 can be stationary while support stage 1012 can reposition wafer 102. In some embodiments, stress-modulation beam 114 can have intensity (e.g., light intensity) that is modulated by changing intensity of beam source 1002 and/or placing a partially absorbing or partially reflecting material at some location between beam source 1002 and wafer 102. This enables delivery of local irradiation doses n(x, y) to various locations of wafer 102. Scanning with stress-modulation beam 114 can occur along multiple directions, e.g., along x-axis and along y-axis according to any suitable predetermined pattern, e.g., back- and forth along x-axis, in a spiral pattern, and so on. In various embodiments, stress-modulation beam 114 can be scanned with a frequency of several Hz, tens of Hz, hundreds of Hz, thousands of Hz, or more.

Operations of irradiation system 1000 can be controlled by a controller 1014, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 1014 can control operations of power element 1006, support stage 1012, and/or various other components and modules of irradiation system 1000. Controller 1014 can include a stress-modification module 1016 capable of performing simulations that determine a target intensity of stress-modulation beam 114 to be used to mitigate various wafer deformations. In some embodiments, as illustrated in FIG. 10B, support stage 1012 can impart a tilt, e.g., in one or two spatial directions to wafer 102 to change an angle of incidence of stress-modulation beam 114 relative to wafer 102. In some embodiments, instead of tilting wafer 102, controller 1014 can cause a tilt of stress-modulation beam 114 relative to wafer 102.

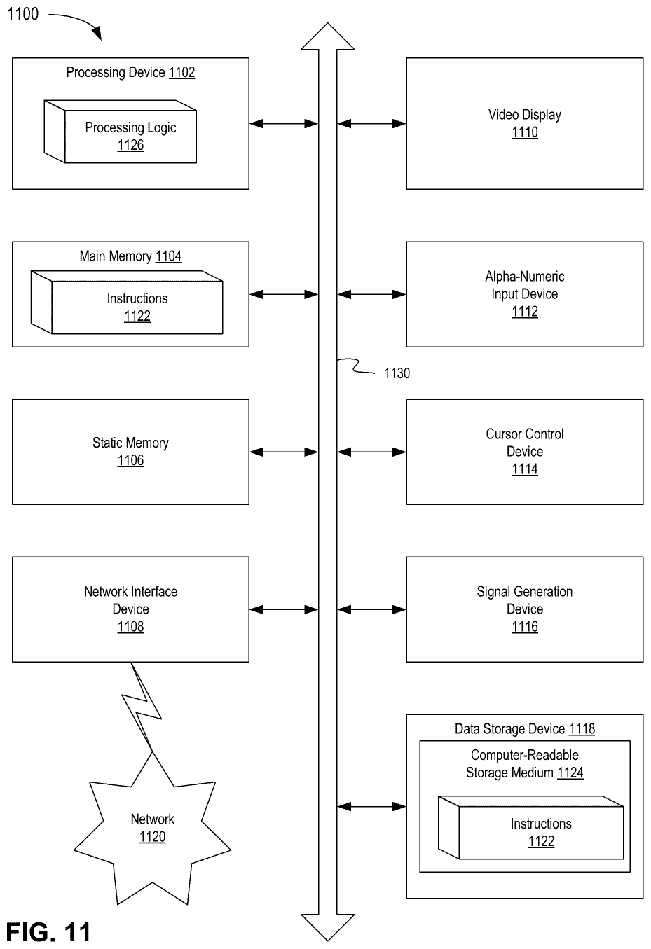

FIG. 11 depicts a block diagram of an example computer system 1100 capable of supporting operations of the present disclosure, according to at least one embodiment. In various illustrative examples, example computer system 1100 may be or include controller 1014 of FIGS. 10A-10B. Example computer system 1100 may be connected to other computer systems in a LAN, an intranet, an extranet, and/or the Internet. Computer system 1100 may operate in the capacity of a server in a client-server network environment. Computer system 1100 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 1100 may include a processing device 1102 (also referred to as a processor or CPU), a main memory 1104 (e.g., read-only memory (ROM), flash memory, dynamic random access memory (DRAM) such as synchronous DRAM (SDRAM), etc.), a static memory 1106 (e.g., flash memory, static random access memory (SRAM), etc.), and a secondary memory (e.g., a data storage device 1118), which may communicate with each other via a bus 1130.

Processing device 1102 represents one or more general-purpose processing devices such as a microprocessor, central processing unit, or the like. More particularly, processing device 1102 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1102 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 1102 may include a processing logic 1126 configured to execute instructions (e.g., instructions 1122) implementing example method 900 of mitigation of wafer deformation using front side and back side stress-compensation films.

Example computer system 1100 may further comprise a network interface device 1108, which may be communicatively coupled to a network 1120. Example computer system 1100 may further comprise a video display 1110 (e.g., a liquid crystal display (LCD), a touch screen, or a cathode ray tube (CRT)), an alphanumeric input device 1112 (e.g., a keyboard), a cursor control device 1114 (e.g., a mouse), and an acoustic signal generation device 1116 (e.g., a speaker).

Data storage device 1118 may include a computer-readable storage medium (or, more specifically, a non-transitory computer-readable storage medium) 1124 on which is stored one or more sets of executable instructions 1122. In accordance with one or more aspects of the present disclosure, executable instructions 1122 may comprise executable instructions implementing example method 900 of mitigation of wafer deformation using front side protection films and back side stress-compensation layers.

Executable instructions 1122 may also reside, completely or at least partially, within main memory 1104 and/or within processing device 1102 during execution thereof by example computer system 1100, main memory 1104 and processing device 1102 also constituting computer-readable storage media. Executable instructions 1122 may further be transmitted or received over a network via network interface device 1108.

While the computer-readable storage medium 1124 is shown in FIG. 11 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
identifying first characteristics of one or more protective films, wherein the first characteristics comprise an amount of stress in each of the one or more protective films;
identifying second characteristics of one or more stress-compensation layers (SCLs), wherein the second characteristics comprise an amount of stress of each of the one or more SCLs;
forming, on a front side of a substrate, the one or more protective films having the first characteristics;
forming, on a back side of the substrate, the one or more SCLs having the second characteristics;
subjecting at least one SCL of the one or more SCLs to a stress-modulation beam, wherein the SCL causes a saddle deformation of the substrate to be reduced; and
removing the one or more protective films.

2. The method of claim 1, wherein the stress-modulation beam comprises at least one of: a beam of ions, a beam of photons, or a beam of electrons.

3. The method of claim 1, wherein the first characteristics further comprise a thickness of each of the one or more protective films, and wherein the second characteristics further comprise a thickness of each of the one or more SCLs.

4. The method of claim 1, wherein at least one SCL of the one or more SCLs is formed after forming a first protective film of the one or more protective films and before forming a second protective film of the one or more protective films.

5. The method of claim 1, wherein the first characteristics and the second characteristics are identified to maintain deformation of the substrate, during formation of the one or more protective films and the one or more SCL, to within a target range of deformations.

6. The method of claim 1, wherein subjecting at least one SCL of the one or more SCLs to a stress-modulation beam comprises:
subjecting the one or more SCLs to the stress-modulation beam having first settings, the first settings comprising a first beam penetration depth; and
subjecting the one or more SCLs to the stress-modulation beam having second settings, the second settings comprising a second beam penetration depth different from the first beam penetration depth.

7. The method of claim 1, wherein subjecting at least one SCL of the one or more SCLs to a stress-modulation beam comprises:
subjecting a first SCL of the one or more SCLs to the stress-modulation beam prior to forming a second SCL of the one or more SCLs.

8. The method of claim 1, wherein a first SCL of the one or more SCLs has a first stress, wherein a second SCL of the one or more SCLs has a second stress, and wherein the first stress has an opposite sign compared to the second stress.

9. The method of claim 8, wherein subjecting at least one of the one or more SCLs to a stress-modulation beam comprises:
exposing the first SCL to a first spatial pattern of irradiation by the stress-modulation beam; and
exposing the second SCL to a second spatial pattern of irradiation by the stress-modulation beam, the second spatial pattern being different from the first spatial pattern.

10. The method of claim 9, wherein the second spatial pattern is rotated, to a predetermined angle, relative to the first spatial pattern.

11. The method of claim 10, wherein the predetermined angle is approximately 90 degrees in a clockwise direction or a counterclockwise direction.

12. The method of claim 9, wherein the first spatial pattern comprises a plurality of edge regions of the first SCL, and wherein each of the plurality of edge regions of the SCL has a width that is at or below 30% of a diameter of the substrate.

13. The method of claim 1, further comprising:
obtaining optical inspection data characterizing a profile of deformation of the substrate, wherein identifying at least the first characteristics of one or more protective films or the second characteristics of one or more SCLs is based at least on the profile of deformation of the substrate.

14. The method of claim 13, further comprising:
obtaining a polynomial decomposition of the profile of the deformation of the substrate, wherein identifying at least the first characteristics of one or more protective films or the second characteristics of one or more SCLs is based at least on the polynomial decomposition of the profile.

15. A system comprising:
a memory; and
a processing device communicatively coupled to the memory, wherein the processing device is to cause performance of operations comprising:
identifying first characteristics of one or more protective films, wherein the first characteristics comprise an amount of stress in each of the one or more protective films;
identifying second characteristics of one or more stress-compensation layers (SCLs), wherein the second characteristics comprise an amount of stress of each of the one or more SCLs;
forming, on a front side of a substrate, the one or more protective films having the first characteristics;
forming, on a back side of the substrate, the one or more SCLs having the second characteristics;
subjecting at least one SCL of the one or more SCLs to a stress-modulation beam, wherein the SCL causes a saddle deformation of the substrate to be reduced; and
removing the one or more protective films.

16. The system of claim 15, wherein at least one SCL of the one or more SCLs is formed after forming a first protective film of the one or more protective films and before forming a second protective film of the one or more protective films.

17. The system of claim 15, wherein the first characteristics and the second characteristics are identified to maintain deformation of the substrate, during formation of the one or more protective films and the one or more SCL, to within a target range of deformations.

18. The system of claim 15, wherein subjecting at least one SCL of the one or more SCLs to a stress-modulation beam comprises:
subjecting the one or more SCLs to the stress-modulation beam having first settings, the first settings comprising a first beam penetration depth; and
subjecting the one or more SCLs to the stress-modulation beam having second settings, the second settings comprising a second beam penetration depth different from the first beam penetration depth.

19. The system of claim 15, wherein subjecting at least one SCL of the one or more SCLs to a stress-modulation beam comprises:
subjecting a first SCL of the one or more SCLs to the stress-modulation beam prior to forming a second SCL of the one or more SCLs.

20. The system of claim 15, wherein a first SCL of the one or more SCLs has a first stress, wherein a second SCL of the one or more SCLs has a second stress, and wherein the first stress has an opposite sign compared to the second stress.

21. A semiconductor manufacturing system comprising one or more processing chambers, the semiconductor manufacturing system to:
identify first characteristics of one or more protective films, wherein the first characteristics comprise an amount of stress in each of the one or more protective films;
identify second characteristics of one or more stress-compensation layers (SCLs), wherein the second characteristics comprise an amount of stress of each of the one or more SCLs;
form, on a front side of a substrate, the one or more protective films having the first characteristics;
form, on a back side of the substrate, the one or more SCLs having the second characteristics;
subject at least one SCL of the one or more SCLs to a stress-modulation beam, wherein the SCL causes a saddle deformation of the substrate to be reduced; and
remove the one or more protective films.
